(19) United States
(12) Patent Application Publication
(10) Pub. No.: US 2009/0036049 A1
(43) Pub. Date: Feb. 5, 2009

(54) CHASSIS HAVING BOTTOM AND REAR-PROVIDED AIR VENTS TO ENABLE AIRFLOW THROUGH THE CHASSIS

(76) Inventors: Ashwin V. Lodhia, Mountain View, CA (US); Mark C. Solomon, Corvallis, OR (US); Thomas H. Szolyga, Saratoga, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/830,723

(22) Filed: Jul. 30, 2007

(51) Int. Cl. H05K 5/00

(52) U.S. Cl. 454/184

(57) ABSTRACT

A system comprises a chassis having a bottom chassis member and a rear chassis member. The system also comprises a base that supports the chassis over a support surface thereby defining an airflow space between the base and the bottom chassis member. The bottom chassis member comprises a first air vent and the rear chassis member comprises a second air vent thereby enabling airflow in to the chassis through the first air vent, through the chassis, and out the second air vent.

### BACKGROUND

As the system designers increase the performance of computer systems, maintaining the system's sufficient cool becomes increasingly more difficult.

### BRIEF DESCRIPTION OF THE DRAWINGS

For a detailed description of exemplary embodiments of the invention, reference will now be made to the accompanying drawings in which:

FIG. 1 shows a side view of a computer system comprising a chassis and a base in accordance with various embodiments; and

FIG. 2 shows a side view of the inside space of the computer's chassis in accordance with various embodiments.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

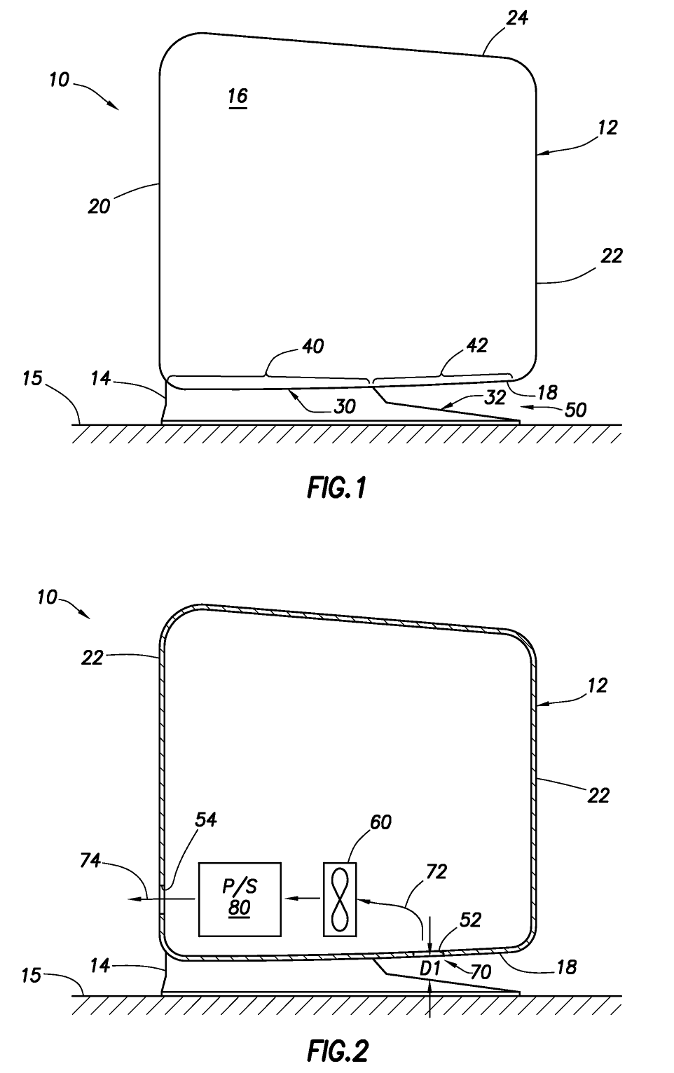

FIG. 1 shows a side view of a computer system 10 in accordance with various embodiments of the invention. The illustrative embodiment shown in FIG. 1 comprises a side view of a computer chassis 12 supported by a base 32 over a support surface 15. In some embodiments the support surface 15 comprises a floor, but the support surface may alternatively comprise a table, desk, etc. The chassis comprises side panels 16 (only one of which can be seen in the side view of FIG. 1).

In some embodiments, the combination of the chassis 12 and the base 14 is referred to as a “tower.” The chassis 12 houses one or more electronic components such as a processor. The chassis 12 generally comprises a bottom chassis member 18, a rear chassis member 20, a front chassis member 22, and a top chassis member 24. The various chassis members 18-24 may comprise separate members joined together (e.g., by screws, welding, etc.) or may be formed from unitary piece of material. The material comprising the chassis members 18-24 comprises metal, plastic, or any other type of suitable material.

The base 14 rests on the support surface 32. A rear portion 30 of the base 32 supports a rearward portion 40 of the bottom chassis member 18 of the chassis 12. A front portion 32 of the base does not directly support the chassis. Thus, a frontward portion 42 of the bottom chassis member 18 is not directly supported by the chassis. As a result of this configuration, a space 50 is defined between the base 14 and the bottom chassis member 18 of the chassis 12.

FIG. 2 also shows a side view of system 10 with the chassis' side panel 16 removed. Referring to FIG. 2, the space 50 permits air to flow in through the bottom of the chassis. As such, the space 50 is referred to as an airflow space. The bottom chassis member 18 comprises a first air vent 52 and the rear chassis member 22 comprises a second air vent 54 through air can flow. The flow of air is indicated by arrows 70, 72, and 74. The chassis 12 also comprises a fan 60 that causes air to be sucked in through air vent 52 generally in the direction of arrow 70, pass through the chassis generally in the direction of arrow 72, and out of the chassis 12 through air vent 54 generally in the direction of arrow 74. Of course, the direction of air flow can be opposite that shown in FIG. 2. The location of the fan 60 may be as shown in FIG. 2 which is between the vent 54 and the power supply 80, in which configuration the fan pushes air through the power supply. Alternatively, the fan 60 may be located at the rear of the chassis (i.e., between the power supply 80 and the rear chassis member 22) in which case the fan essentially “sucks” air through the power supply. Further still, the fan 60 may be located in the bottom of the power supply 80, at or near the bottom of the chassis, in which case the air is pushed up by the fan and into the power supply. In some embodiments, the fan 60 draws from the bottom of the chassis, while in other embodiments, the fan draws air from the front of the chassis. In some embodiments, the power supply has its own fan and a separate chassis fan is provided. In such embodiments, the power supply fan draws air in from the bottom of the chassis and blows it out the back, and the chassis fan which may be mounted near the front of the chassis draws air in from the front of the chassis and blows it out the back. The chassis fan may also blow air across one or more hard disk drives (not specifically shown) mounted at or near the bottom of the chassis.

FIG. 2 also illustrates that a power supply 80 is provided internal to the chassis. The power supply 80 in the embodiment of FIG. 2 converts input alternating current (AC) voltage to a suitable direct current (DC) voltage for use by the electrical components housed in the chassis 12. In some embodiments, the power supply 80 is mounted in chassis 12 generally adjacent the bottom and rear chassis members 18 and 20. Being “adjacent” the bottom and rear chassis members 18 and 20 means that the power supply 80 is mounted on or near the bottom and rear chassis members 18, 20. In some embodiments, the power supply, for example, is mounted within four inches of the bottom or rear chassis members 18, 24. The power supply 18 tends to be a relatively heavy component of the system 10. With the chassis 12 supported only along a rearward portion 40 (FIG. 1) of the bottom chassis member 18, the location of the power supply 80, being in the back and bottom of the chassis 12, helps to avoid the chassis from being top heavy and falling over. Further, the power supply 80, which tends to generate considerable heat, is in or near the flow of air along the direction defined by arrows 70, 72, and 74. This flow of air helps to remove heat from the power supply 80.

In some embodiments, the space between the base 14 and the bottom chassis member 18 is such that the distance (denoted by D1 in FIG. 2) from the base 14 to the air vent 52 in the bottom chassis member is at least one-half inch. In some embodiments, D1 is from 1 to 3 inches. The distance D1 can be varied as desired.

The above discussion is meant to be illustrative of the principles and various embodiments of the present invention. Numerous variations and modifications will become apparent to those skilled in the art once the above disclosure is fully appreciated. It is intended that the following claims be interpreted to embrace all such variations and modifications.

What is claimed is:

1. A system, comprising:
a chassis comprising a processor, said chassis having a bottom chassis member and a rear chassis member; and
a base that supports said chassis over a support surface thereby defining an airflow space between said base and said bottom chassis member;
wherein said bottom chassis member comprises a first air vent and said rear chassis member comprises a second air vent thereby enabling airflow in to the chassis through said first air vent, through said chassis, and out said second air vent.

2. The system of claim 1 further comprising a power supply mounted in said chassis adjacent said bottom chassis member.

3. The system of claim 2 wherein said airflow removes heat generated by the power supply.

4. The system of claim 1 wherein said chassis is supported by the base at a rear portion of said bottom chassis member.

5. The system of claim 1 wherein said chassis is supported by the base at a rear portion of said bottom chassis member, but not along an entire length of said bottom chassis member.

6. The system of claim 1 further comprising a fan that moves air from said first air vent, through said chassis, and out said second air vent.

7. The system of claim 1 further comprising a power supply and a fan, wherein said fan moves air from said first air vent, through said chassis, in or around said power supply, and out said second air vent, to thereby remove heat generated by the power supply.

8. The system of claim 1 wherein the airflow space comprises a distance from said base to said first air vent in the bottom chassis member of at least one-half inch.

9. A system, comprising:
means for housing a processor;
means for supporting said means for housing over a support surface; and
means for passing air from a space between said means for housing and means for support.

10. The system of claim 9 further comprising means for causing air to flow through said space.
